(19) United States
(12) Patent Application Publication
(10) Pub. No.: US 2004/0098643 A1
(43) Pub. Date: May 20, 2004

(54) Method and apparatus for accessing internal RAMs during diagnostic testing

(76) Inventor: Jurgen Schulz, Pleasanton, CA (US)

Correspondence Address: B. Noel Kivlin, Conley, Rose, & Tayon, P.C., P.O. Box 398, Austin, TX, 78767, US

(21) Appl. No.: 10/298,386

(22) Filed: Nov. 18, 2002

(51) Int. Cl. G11C 29/00

(52) U.S. Cl. 714/718

(57) ABSTRACT

A method and apparatus for accessing the contents of an internal RAM during diagnostic testing. In one embodiment, an integrated circuit includes an internal memory. A scan chain may be coupled to the internal memory. A first segment of the scan chain may be coupled to control and address inputs to the memory. A second segment of the scan chain may be coupled to the data lines of the memory. Address and control signals may be input into the integrated circuit through the scan chain, which may then provide the signals to the memory itself. The address and control signals may read enable the memory as well as selecting an address to be read. The memory contents of the selected address may be captured by flip-flops in the second segment of the scan chain. The memory contents may be shifted from the integrated circuit through the scan chain.

### BACKGROUND OF THE INVENTION

1. Field of the Invention

This invention relates to the testing of electronic circuits, and more particularly, the accessing of an internal RAM (random access memory) during the testing of an integrated circuit.

2. Description of the Related Art

In any new integrated circuit design, testability is often times an important factor to be considered. However, due to the increasing density of integrated circuits, design for testability has become a much greater challenge. Integrated circuits having a large scale of integration may be difficult to test by simply applying external stimuli. Thus, testing circuits having a large scale of integration may involve the use of scan chains in order to input test vectors.

Scan chains within an integrated circuit may be created by serially coupling a large number of storage devices (e.g. flip-flops). The scan chains may pass through the internal logic of an integrated circuit, and may allow data to be input for testing purposes. Test vectors may be serially shifted into the integrated circuit via the scan chain, thereby loading each of the elements of the scan chain with a predetermined value. Subsequent to loading the test vectors, the integrated circuit may be placed in its normal operating mode. Placing the integrated circuit in its normal operating mode may cause the various internal logic circuits to respond to the test vectors. After allowing a certain amount of time for the circuits to respond, the integrated circuit may be returned to a scan mode, and the resulting test data may be scanned out via the scan chain.

Many large scale integrated circuits include internal memories, such as an internal RAM (random access memory). While testing as described above may be an effective method for testing the various logic circuits of an integrated circuit, the method may be unable to test the functionality of an internal RAM. Furthermore, it may be desirable during testing to read the contents of various locations within an internal RAM in order to verify the functionality of internal chip logic. However, it may not be possible to read out the contents of various memory locations through the scan chain. Thus, such integrated circuits may be shipped with little or no testing of internal RAM.

### SUMMARY OF THE INVENTION

A method and apparatus for accessing the contents of an internal RAM during diagnostic testing is disclosed. In one embodiment, an integrated circuit includes an internal memory. A scan chain including a plurality of serially coupled flip-flops may be coupled to the internal memory. A first segment of the scan chain may be coupled to control and address inputs to the memory. A second segment of the scan chain may be coupled to the data lines of the memory. Address and control signals may be input into the integrated circuit through the scan chain, which may then provide the signals to the memory itself. The address and control signals may read enable the memory as well as selecting an address to be read. The memory contents of the selected address may be captured by flip-flops in the second segment of the scan chain. The memory contents may then be shifted from the integrated circuit through the scan chain. The inputting of control and address signals and outputting of memory contents via the scan chain may be repeated until the memory access is complete.

### BRIEF DESCRIPTION OF THE DRAWINGS

Other aspects of the invention will become apparent upon reading the following detailed description and upon reference to the accompanying drawings in which:

FIG. 1 is a block diagram of one embodiment of an application specific integrated circuit (ASIC) including an internal random access memory (RAM);

FIG. 2 is a block diagram of one embodiment of a scan chain which may be used to input data during the testing of an integrated circuit;

FIG. 3 is a block diagram of one embodiment of a RAM collar internal to an integrated circuit; and

FIG. 4 is a flow diagram of one embodiment of a method for performing an internal RAM dump.

While the invention is susceptible to various modifications and alternative forms, specific embodiments thereof are shown by way of example in the drawings and will herein be described in detail. It should be understood, however, that the drawings and description thereto are not intended to limit the invention to the particular form disclosed, but, on the contrary, the invention is to cover all modifications, equivalents, and alternatives falling with the spirit and scope of the present invention as defined by the appended claims.

### DETAILED DESCRIPTION OF THE INVENTION

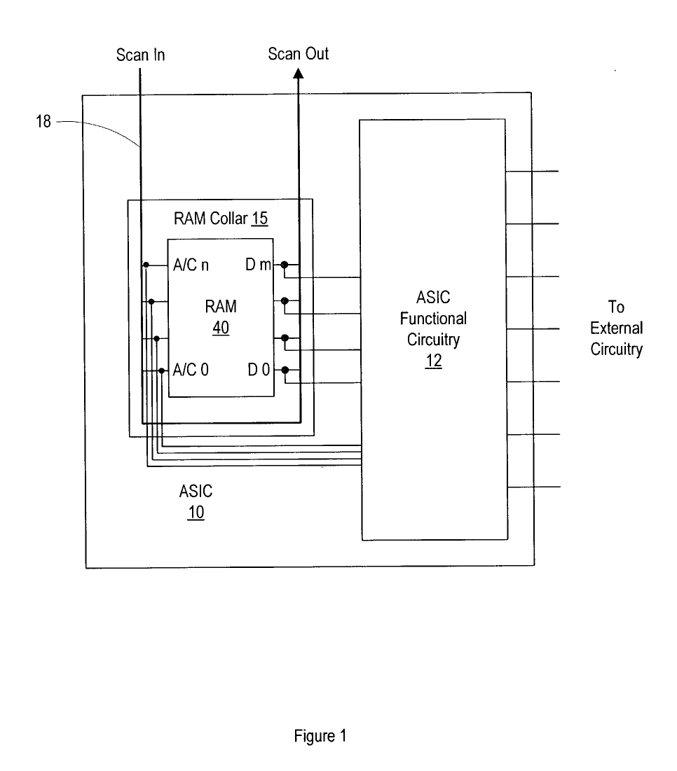

Turning now to FIG. 1, a block diagram of one embodiment of an application specific integrated circuit (ASIC) including an internal random access memory (RAM) is shown. The embodiment shown in FIG. 1 is an application specific integrated circuit (ASIC). ASIC 10 may be virtually any kind of integrated circuit, and includes ASIC functional circuitry 12 and RAM collar 15. An internal RAM 40 is present within RAM collar 15. RAM collar 15 may also include additional circuitry (not shown) that may be necessary for accessing RAM 40. ASIC functional circuitry 12 may be logic that performs the various functions for which ASIC 10 was designed. Functional circuitry 12 may also be coupled to RAM 40 by a plurality of data lines and address/control lines. Control and address signals may be generated by functional circuitry 12 in order to access RAM 40 for reads or writes. Data may be transmitted between functional circuitry 12 and RAM 40 over a plurality of signal lines that are coupled to the data I/O pins of RAM 40.

ASIC 10 includes a scan chain 18. Embodiments having additional scan chains are possible and contemplated. Scan chain 18 may be used to shift test vectors or other test stimuli into ASIC 10. The test vectors/stimuli, when input into ASIC 10, may elicit a response from various portions of RAM collar 15 or functional circuitry 12. After the circuitry has responded to the test vectors/stimuli, the response data may be loaded into the scan chain and shifted out of ASIC 10 where it may be observed in order to determine the results of the testing. In addition to providing test data/stimuli, scan chain 18 may be used to convey control and address signals into RAM collar 15 and/or RAM 40. Scan chain 18 may also be used capture data that is read from an address in RAM 40 (the address specified by signals input via scan chain 18). The data read from RAM 40 and captured by the scan chain may also be shifted out of ASIC 10 for observation.

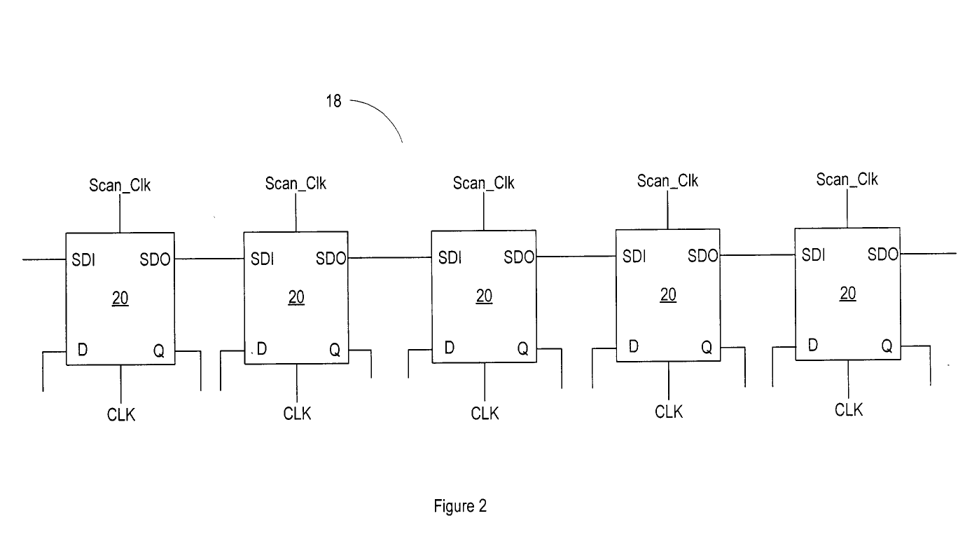

Moving now to FIG. 2, a block diagram of one embodiment of a scan chain which may be used to input data during the testing of an integrated circuit is shown. In the embodiment shown, scan chain 18 includes a plurality of serially coupled scannable state elements 20. In this particular embodiment, the scannable state elements 20 are D-type flip-flops that also have inputs and outputs for scan data (SDI and SDO, respectively). Scannable state elements 20 may be coupled together by linking the scan data output (SDO) of one element to the scan data input (SDI) of another element. The D input and Q output of each scannable state element 20 may be coupled to other logic elements (which may be combinational or sequential logic) within ASIC 10, and the D-type flip-flop may function as a storage element or other clocked circuit. It should be noted that, in some embodiments, the Q and SDO outputs may be electrically connected to each other, while in other embodiments, the Q and SDO output may be electrically separate.

Generally speaking, a scannable state element may be any clocked storage device having scan functionality built in. Such clocked storage devices may include flip-flops, latches, registers, and other devices.

Data may be shifted through scan chain 18. During shifting, data may pass from the SDO output of a scannable state element 20 to the SDI input of the next scannable state element 20 in the chain. Data that is shifted into a scannable state element 20 may also be used to set the state of its respective Q output.

During the shifting of data through scan chain 18, each of scannable state elements 20 may be synchronized to a scan clock signal (Scan_clk). With each cycle of the scan clock signal, data may be shifted from one scannable state element 20 to the next. If it is desired to set the state of the Q output of a given scannable state element, the setting of the state may also be synchronized to the scan clock. During normal operations of the circuit in which scan chain 18 is implemented, each scannable state element may be synchronized to a chip clock signal (CLK). During the shifting of the data through scan chain 18, the chip clock signal provided to scannable state elements 20 may be inhibited. Once the shifting is complete, the scan clock may be inhibited. If necessary, the chip clock may be allowed to run during the testing of surrounding circuitry in order that it may respond to the test vectors scanned in through scan chain 18.

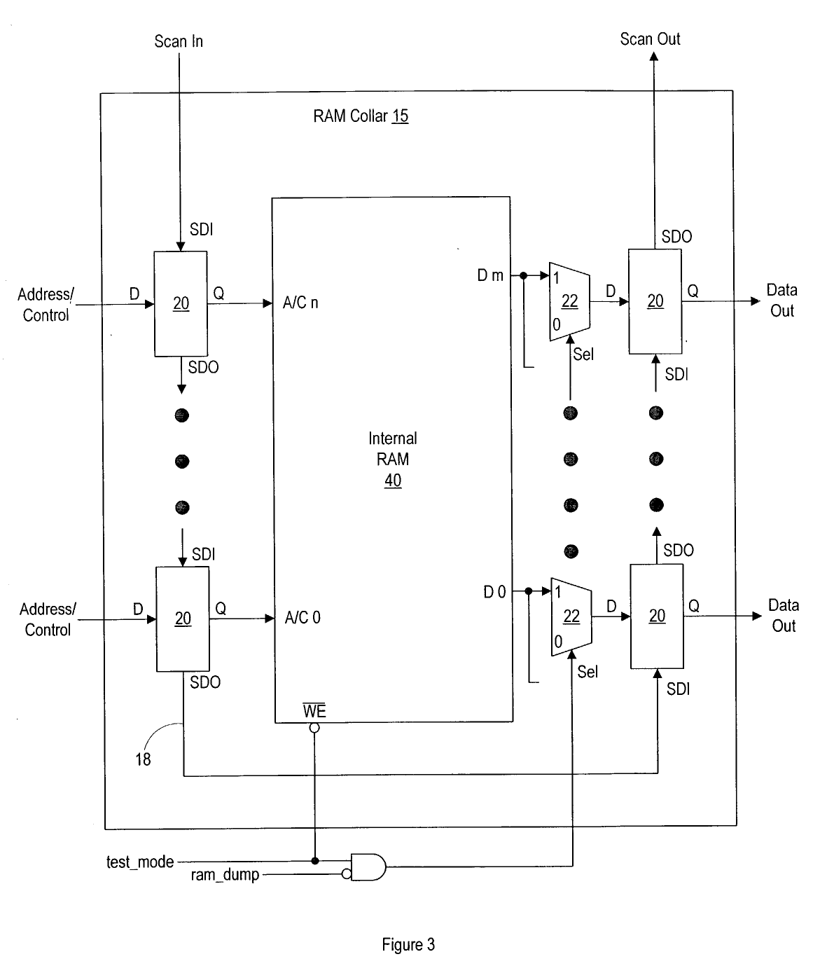

Turning now to FIG. 3, a block diagram of one embodiment of a RAM collar internal to an integrated circuit is shown. In the embodiment shown, RAM collar 15 includes a RAM 40. Internal RAM 40 may be coupled to a plurality of scannable state elements 20 of chain 18. A first segment of scan chain 18 may include a plurality of scannable state elements 20 which are coupled to address or control inputs of internal RAM 40. A second segment of scan chain 18 may include a plurality of scannable state elements 20 which are coupled to data inputs/outputs of internal RAM 40 via multiplexers 22 (which may not be present in some embodiments).

Internal RAM 40 may be any type of random access memory. Internal RAM 40 may be of any storage capacity that may be accommodated by the integrated circuit in which it is implemented. During the normal operation of the integrated circuit, internal RAM 40 may be used provide storage for data generated by the operation of the chip's internal logic circuitry, and may also store instructions that may be executed by various functional units within the chip.

During scanning operations, as well as during read operations, it may be necessary to prevent writes into internal RAM 40. In the embodiment shown, a test mode signal (test_mode) may be asserted as a logic high during scanning and testing operations. The test_mode signal may be received by the write enable input of internal RAM 40. During normal write operations, the write enable signal may be asserted as a logic low. Thus, writes to internal RAM 40 may be inhibited in this embodiment when the test_mode signal is asserted. When the test mode signal is de-asserted, RAM 40 may operate in a normal functional mode, thereby allowing normal reads and writes.

In the embodiment shown, RAM collar 15 may be configured to support a built-in self-test (BIST). In particular, the presence of multiplexers 22 support the BIST. When the test_mode signal is asserted while the ram_dump signal is de-asserted, the value on the ‘0’ input of the multiplexer 22 may be allowed to propagate through to an associated scannable state element 20. The value present on the ‘0’ input of each multiplexer 22 may be hardwired to a logic high or a logic low value for some embodiments. When both the test_mode and ram_dump signals are asserted, the value on the output of the AND gate may be driven to a logic high, thereby allowing the value present on the ‘1’ input of each multiplexer 22 to propagate through to an associated scannable state element 20. In this manner, the scannable state elements 20 of scan chain 18 may be used to capture the contents of addresses in internal RAM 40.

The memory contents that are captured in the scan chain may be determined by the inputs to the address and control inputs. Both address and control signals may be input into internal RAM 40 via scan chain 18. A separate scannable state element 20 may be present for each address bit that is necessary to select a memory location within internal RAM 40. Additional scannable state elements 20 may also be present for each control input necessary to perform read operations on internal RAM 40. Such control inputs may include one or more write enable signals, read enable signals, and any inputs necessary to access specific addresses in the RAM. The address and control input signals may be used to set the state (‘Q’) of their appropriate scannable state elements 20. The logic state present on the ‘Q’ output of each scannable state element may propagate to its respective address or control input. This may result in enabling a specific address of the memory to be read. When all of the control and address signals have been input into internal RAM 40, the address or addresses to be read may be selected. The contents of the selected address or addresses may be ‘dumped’ into scannable state elements 20 (via multiplexers 22 in this particular embodiment) from the data lines of internal RAM 40. Once the contents to be read have been loaded into scannable state elements 20, scan operations may resume, thereby allowing the contents to be shifted from the integrated circuit for external observation.

Since internal RAM 40 is normally only accessible to internal logic of the integrated circuit in which it is implemented, the ability to read its contents may be useful in conducting diagnostic testing of internal logic. For example, test vectors may be input into the integrated circuit in order to test the operation of various logic circuits. The operation of these logic circuits may cause write operations to internal RAM 40. The testing of the internal logic may include inputting test vectors in order to cause these writes to occur. Following the writes to internal RAM 40, operation of the integrated circuit may be suspended, thereby allowing address and control signals to be input via scan chain 18. The address and control signals may then cause the contents of a memory address to be captured by scannable state elements 20 of scan chain 18. The memory contents may then be shifted from the integrated circuit where they may be observed, and thus allowing a determination to be made if the correct contents were written into internal RAM 40 during the operation of the internal logic of the integrated circuit.

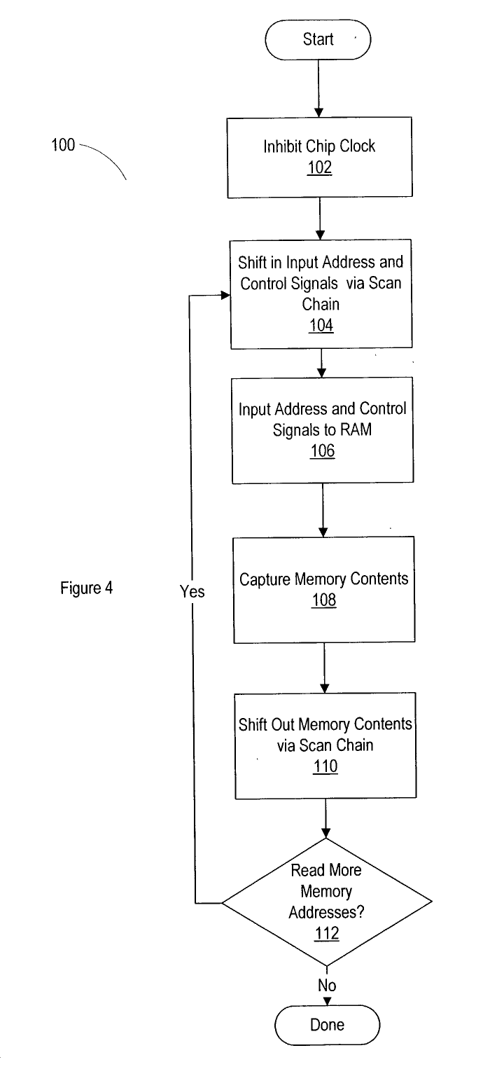

FIG. 4 is a flow diagram of one embodiment of a method for performing an internal RAM dump. Method 100 may begin with the inhibiting of a chip clock (item 102). In particular, a chip clock that is used to synchronize the internal logic of an integrated circuit (such as that shown in FIG. 1) may be stopped or otherwise be prevented from being input into the integrated circuit. This may result in a suspension or halt of operations within the integrated circuit. Once the chip clock has been inhibited, a scan clock signal may be input to scannable state elements in a scan chain, such as those illustrated in FIGS. 2 and 3.

Once the scan clock is running, address and control signals may be shifted into a first segment of the scan chain, wherein the elements of the first segment are each coupled to an address or control input of the internal RAM. When the shifting of the signals is complete the output state of each scannable state element (e.g. the ‘Q’ output shown in either FIG. 2 or 3) may be set to a state determined by the input signal shifted in. The set state may then propagate to its respective input, which results in the inputting of address and control signals to the RAM (item 106).

The inputting of address and control signals may select a memory address or group of memory addresses. The contents of the selected address(es) may propagate to the data lines of the RAM, which thereby allows scannable state elements of a second segment of the scan chain to capture the contents (item 108). Each data line may convey a single bit of information to a scannable state element.

Once the memory contents have been successfully captured, scan operations may resume. The resumption of scan operations may result in the shifting of memory contents from the integrated circuit through the scan chain (item 110). The memory contents may be shifted out of the integrated circuit and into a location where they can be stored for future observation.

In many cases, it may be necessary to read multiple memory addresses over several read cycles. Thus, the method may perform a check (item 112) to determine if more addresses are to be read. If the contents of additional memory addresses are to be captured, the method may repeat items 104 through 112.

While the present invention has been described with reference to particular embodiments, it will be understood that the embodiments are illustrative and that the invention scope is not so limited. Any variations, modifications, additions, and improvements to the embodiments described are possible. These variations, modifications, additions, and improvements may fall within the scope of the inventions as detailed within the following claims.

What is claimed is:

1. A method for accessing a memory internal to an integrated circuit during testing, the method comprising:
inhibiting a chip clock;
inputting memory address and control signals into the integrated circuit from a first segment of a scan chain;
capturing memory contents in a second segment of the scan chain;
outputting the memory contents from the integrated circuit through the scan chain;
and
repeating said inputting, said capturing, and said shifting until said accessing is complete.

2. The method as recited in claim 1 further comprising entering a test mode responsive to asserting a test mode signal.

3. The method as recited in claim 2 further comprising asserting a memory dump signal.

4. The method as recited in claim 2 further comprising inhibiting a memory write function.

5. The method as recited in claim 1, wherein the scan chain includes a plurality of serially coupled flip-flops.

6. The method as recited in claim 5, wherein said inputting includes serially shifting the memory address and control signals into the integrated circuit through the scan chain.

7. The method as recited in claim 6, wherein said outputting includes serially shifting the memory contents from the integrated circuit through the scan chain.

8. The method as recited in claim 7, wherein said shifting is synchronized by a scan clock signal.

9. The method as recited in claim 5, wherein the flip-flops are D-type flip-flops.

10. The method as recited in claim 1, wherein the memory is a random access memory (RAM).

11. The method as recited in claim 10, wherein the memory is a static RAM (SRAM).

12. An integrated circuit comprising:
an internal memory; and
a scan chain, wherein a first segment of the scan chain is coupled to control and address inputs of the internal memory and wherein a second segment of the scan chain is coupled to data lines of the internal memory;
wherein the integrated circuit is configured to receive internal memory address and control signals through the first segment of the scan chain, and, responsive to receiving the internal memory address and control signals, to capture internal memory contents in the second segment of the scan chain and output the internal memory contents through the second segment of the scan chain.

13. The integrated circuit as recited in claim 12, wherein the integrated circuit is configured to enter a test mode responsive to receiving a test mode signal.

14. The integrated circuit as recited in claim 13, wherein the integrated circuit is further configured to receive an internal memory dump signal.

15. The integrated circuit as recited in claim 13, wherein the test mode signal, when asserted, inhibits writes to the internal memory.

16. The integrated circuit as recited in claim 12, wherein the scan chain includes a plurality of serially coupled flip-flops.

17. The integrated circuit as recited in claim 16, wherein the internal memory address and control signal are serially shifted into the integrated circuit through the scan chain.

18. The integrated circuit as recited in claim 17, wherein the integrated circuit is configured to output the internal memory contents by serially shifting the internal memory contents from the integrated circuit through the scan chain.

19. The integrated circuit as recited in claim 18, wherein said serially shifting is synchronized by a scan clock signal.

20. The integrated circuit as recited in claim 16, wherein the flip-flops are D-type flip-flops.

21. The integrated circuit as recited in claim 12, wherein the internal memory is a random access memory (RAM).

22. The integrated circuit as recited in claim 21, wherein the internal memory is a static RAM (SRAM).
